(19) United States
(12) Patent Application Publication
(10) Pub. No.: US 2019/0256973 A1
(43) Pub. Date: Aug. 22, 2019

(54) Method and Apparatus for Depositing Diamond-Like Carbon Coatings

(71) Applicant: Southwest Research Institute, San Antonio, TX (US)

(72) Inventors: Ronghua Wei, San Antonio, TX (US); Christopher Rincon, San Antonio, TX (US)

(21) Appl. No.: 15/901,348

(22) Filed: Feb. 21, 2018

(51) Int. Cl. C23C 16/27; C23C 16/02; C23C 16/515; C23C 8/36; H01J 37/32

(52) U.S. Cl. CPC C23C 16/276; C23C 16/0272; H01J 37/32412; C23C 8/36; C23C 16/515

(57) ABSTRACT

A method of forming a coating including providing a component within a mesh cage in a chamber, wherein the mesh cage is coupled to a first power supply and the component is coupled to a second power supply. A coating is deposited on the component, wherein depositing the coating includes supplying a coating precursor gas to the chamber, applying a pulsed voltage to the mesh cage with the first power supply generating a plasma, and applying a voltage to the component. The method may provide a diamond-like coated component includes diamond-like carbon coating on the surface of the component exhibiting a thickness in the range of 10 μm to 40 μm and a hardness, as determined by nanoindentation, in the range of 10 GPa to 25 GPa.

### FIELD

The present disclosure is directed to a plasma immersion ion deposition process for applying coatings on three-dimensional components utilizing a mesh cage chamber coupled to a first power supply where the components are coupled to a second power supply to draw ions to the component surface.

### BACKGROUND

Generally, in plasma immersion ion deposition systems, such as system 100 illustrated in FIG. 1, processes components 102 are placed on a metal plate 104, i.e., a work table, within a vacuum chamber 106. When the worktable is biased with a negative, relatively high (˜5 kV) pulsed voltage by, e.g., a pulsed DC power supply 108, a glow discharge plasma 110 is formed around the table and the component. The relatively high voltage also draws the ions from the plasma to the worktable. When an appropriate precursor, such as acetylene, is used for the plasma discharge, a diamond-like carbon coating can be deposited on the component surface. However, this process may result in relatively low deposition rates, approximately 0.1 μm/hour to 0.5 μm/hour, and relatively thin coatings, having a thickness of less than 5 μm. In addition, this process may result in relatively poor coverage for three-dimensional components. The deposition rate, coating thickness, and coverage may be due to relatively low plasma density.

To address the issue of relatively low plasma density, a hollow cathode discharge process was developed to form the diamond-like carbon coatings. When a relatively high voltage is applied to a hollow tube, into which parts are placed, plasma is generated inside the tube. The electrons in the plasma are drawn to the vacuum chamber wall by the voltage potential. On the way, the electrons inside the tube experience many collisions with neutrals, generating more ions before losing energy. When they migrate to the ends of the tube, they are drawn to the chamber wall and complete the electrical circuitry. A drawback of this process, however, is that it generates carbon dust that may fall on the part surface during deposition, which may contaminate the coating.

In U.S. Pat. No. 8,252,388 a meshed plasma immersion ion deposition process is described. The system 200 is illustrated schematically in FIG. 2. A component 202 is placed inside of a meshed cage 204 within a vacuum chamber 206, instead of a hollow tube, to reduce the likelihood of carbon dust falling on the part surface during deposition. Using a power supply 208, a relatively high voltage was applied to the mesh cage to generate plasma 210. This process increased the deposition rate to 1 μm/hr to 3 μm/hr, the maximum coating thickness increased to up to 50 μm and coating coverage on 3-D components was increased. However, the coating hardness was found to be relatively low, at less than 10 GPa, which is due to the coatings being formed by low energy ions generated by the electron-neutral collisions inside the mesh cage.

Accordingly, room for improvement remains developing methods and systems for depositing diamond-like coatings, as well as other coatings, to provide coatings that exhibit a relatively greater hardness, while still maintaining relatively high deposition rates and coating thicknesses.

### SUMMARY

An aspect of the present disclosure relates to a method of forming a coating. The method includes providing a component within a mesh cage in a chamber, wherein the mesh cage is coupled to a first power supply and the component is coupled to a second power supply. The pressure within the chamber is reduced to a pressure below atmospheric pressure. Depositing the coating on the component includes supplying a coating precursor gas to the chamber at a rate in the range of 50 sccm to 200 sccm, applying a pulsed voltage to the mesh cage with the first power supply to generate a plasma, and applying a voltage to the component. The pulsed voltage applied to the mesh cage is in a range of 1 kV to 3 kV, at a frequency in the range of 1 kHz to 4 kHz, and a pulsed width in the range of 10 μs to 30 μs. The voltage applied to the component is set in the range of 100 V to 800 V. The pulsed voltage and the voltage are applied for a period of time in the range of 1 hour to 20 hours.

In embodiments, the method may also include depositing a bond layer on the component prior to depositing the coating. Depositing the bond layer preferably includes supplying a bond layer precursor gas to the chamber at a rate in the range of 10 sccm to 30 sccm, applying the pulsed voltage to the mesh cage with the first power supply to generate a plasma, applying the voltage to the component, and forming a bond layer on said component. The pulsed voltage applied to the mesh cage is set in a range of 1 kV to 3 kV, at a frequency in the range of 1 kHz to 4 kHz, and a pulsed width in the range of 10 μs to 30 μs. The voltage applied to the component is set in the range of 100 V to 800 V. And, the pulsed voltage and the voltage are applied for a period of time in the range of 10 minutes to 60 minutes. The coating is then formed on the bond layer.

In embodiments of the above, whether or not a bond layer is applied, the method may also include cleaning a component prior to depositing the coating (or the bond layer). Cleaning the component includes supplying an inert gas to said chamber at a rate in the range of 1 sccm to 200 sccm. The pulsed voltage may be applied to the mesh cage with the first power supply generating a plasma, is set in the range of 1 kV to 5 kV, at a frequency in the range of 0.5 kHz to 6 kHz, and a pulsed width in the range of 10 μs to 30 μs. In addition, the voltage applied by the second power supply to the component is set in the range of 50 V to 1,000 V.

Another aspect of the present disclosure relates to a diamond-like coated component. The component includes a surface and a diamond-like coating deposited on the surface, wherein the diamond-like coating exhibits a thickness in the range of 1 μm to 40 μm and a hardness, as determined by nanoindentation, in the range of 10 GPa to 25 GPa. Preferably, the diamond-like coating is a diamond-like coating characterized as being formed by the methods set forth above.

### BRIEF DESCRIPTION OF THE DRAWINGS

The above-mentioned and other features of this disclosure and the manner of attaining them will become more apparent with reference to the following description of embodiments herein taking in conjunction with the accompanying drawings, wherein:

FIG. 1 is a schematic of an embodiment of a plasma immersion ion deposition system;

FIG. 2 is a schematic of another embodiment of a plasma immersion ion deposition system;

FIG. 3 is a schematic of another embodiment of a plasma immersion ion deposition system;

FIG. 4a is an SEM image of a DLC coating formed by applying a bias to just the mesh cage, wherein the SEM image was taken at 1000× magnification;

FIG. 4b is an SEM image of a DLC coating formed by applying a bias to just the mesh cage, wherein the SEM image was taken at 2000× magnification;

FIG. 5a is an SEM image of a DLC coating formed by applying a bias to both the mesh cage and the component, wherein the SEM image was taken at 1000× magnification; and

FIG. 5b is an SEM image of a DLC coating formed by applying a bias to both the mesh cage and the component, wherein the SEM image was taken at 2000× magnification;

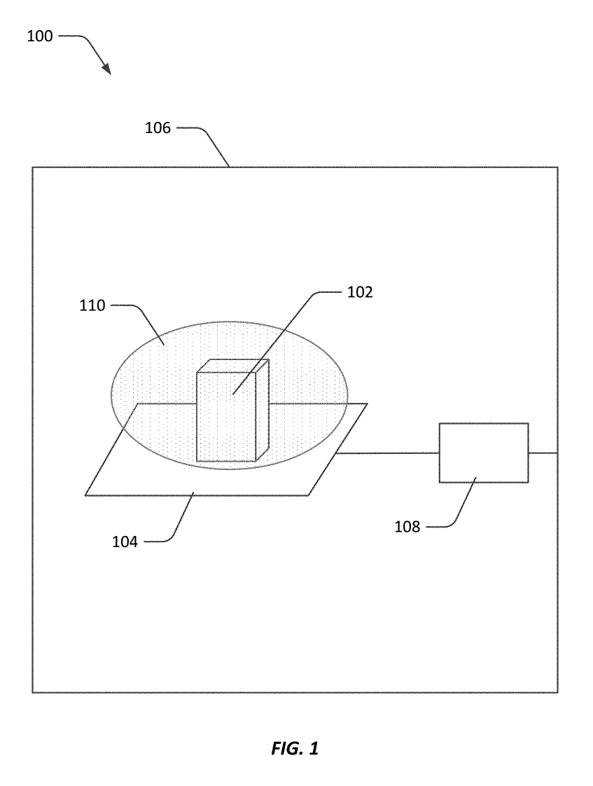

### DETAILED DESCRIPTION

The present disclosure is directed to a plasma immersion ion deposition process for applying coatings, and particularly diamond-like carbon coatings, on three-dimensional component surfaces. The process utilizes a mesh cage to enclose the component; however, in addition to applying power to the mesh cage, power is separately applied to the component. Without being bound to any particular theory, this arrangement decouples plasma generation and ion acceleration. In particular embodiments, diamond-like carbon coatings are deposited on the component surfaces; however, other coatings may also be deposited with the process and system.

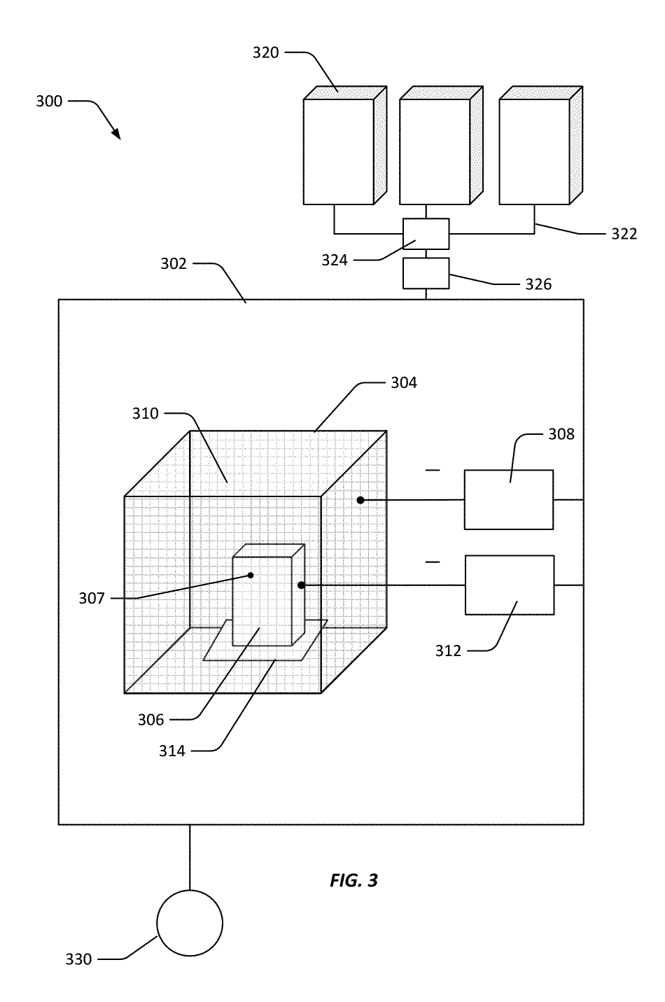

A general embodiment of a system for depositing the coatings is illustrated in FIG. 3. The apparatus 300 includes a chamber 302, which is preferably a vacuum chamber. The chamber may include a metal container made of metal plates and/or foils. The container has at least one opening to provide gas therein, as further described below, and allow electrons to escape.

Positioned within the chamber is a mesh cage 304. The one or more components 306 are placed within the mesh cage 304. The mesh cage may be formed from one or more conductive materials, such as stainless steel. The openings in the mesh are preferably 3 mm or less, including all values and ranges from 0.5 mm to 2 mm. The mesh cage may generally define a three-dimensional shape, such as cube, cylinder, or other polyhedra. Ten percent to 98 percent of the surface area of the polyhedral may be open, including all values and ranges therein. Preferably, the metal cage encloses the components on all side, yet the open nature of the mesh cage allows for gas, plasma, electrons, etc., to pass through the cage. In addition, the mesh cage does not directly contact the component surfaces 307. Insulators may be utilized to offset and support the metal cage from the component surfaces. In embodiments, the mesh cage may be formed from screen, perforated sheet, or woven ribbons of the conductive material. The shape of the cage need not be the same as that of the component being coated, but in some embodiments may exhibit the same geometry, except larger such that the distance D between the cage and any point on the surface of the component is preferably in the range of 20 mm to 100 mm.

The components include three-dimensional objects and may exhibit any number of characteristics including holes, depressions, sharp angles, projections, etc. Further, the component may be conductive or non-conductive. If non-conductive, the component is preferably positioned on a conductive plate. Accordingly, the components may be formed from metal, metal alloy, semi-conductor materials such as silicon, polymeric materials including thermoplastics or thermosets, wood, composites, glass, etc.

A first power supply 308 is coupled to the mesh cage 304 to generate plasma 310 from the process gasses supplied to the chamber by pulsed hollow cathode discharge (if a high plasma density is needed) or pulsed glow discharge (if a low plasma density is needed). Pulsed hollow cathode discharge or pulsed glow discharge is the formation of plasma by the passage of an electric current, applied by electrode, through a gas. Pulsed hollow cathode discharge is characterized by a high peak current of 1 A to 300 A, and typically 100 A, while pulsed glow discharge is characterized by low peak current of 0.01 A to 1 A, and typically 0.5 A. The first power supply applies a pulsed voltage to provide a negative bias to the mesh cage. A second power supply 312 is coupled to the component 306 or a work table 314 upon which the component is placed to apply a negative bias to the component and accelerate the ions of the plasma towards the component 306. The mesh cage 304 provides a first electrode and the component 306 (or work table 314) provides a second electrode.

Process gasses are supplied to the chamber through a feed system, which include one or more storage containers 320 and a feed line 322 coupled between the storage containers 320 and the chamber 302. The feed line 322 may also include one or more flow control devices 324 and temperature control units 326 attached thereto. Exemplary flow control devices may include valves, mass flow controllers, volumetric flow controllers, static mixers, etc. Exemplary temperature control units may include heaters or coolers. In addition, one or more vacuum pumps 330 are preferably affixed to the chamber 302.

A method of depositing a coating optionally begins with the ion cleaning of the surfaces of the component using an inert gas, such as argon or hydrogen. After cleaning, a bond layer is optionally applied on the surfaces using a bond layer precursor gas. The bond layer precursor gas may include e.g., silicon, such as silane (SiH₄) or trimethylsilane (TMS). A diamond-like carbon coating is then deposited using a coating precursor gas, such as methane (CH₄), acetylene (C₂H₂), silane (SiH₄), or trimethylsilane (TMS). Preferably, the diamond-like coating is a diamond-like carbon coating containing carbon. Alternative or additional coatings, such as transition metal coatings, including e.g., chromium or titanium, may be applied with transition metal containing precursor gasses, such as hexacarbonyl chromium (Cr(CO)₆) or tetrakis titanium (Ti[N(CH₃)₂]₄). In a preferred embodiment, after optional ion cleaning of the component surface, a bond layer is applied using trimethylsilane precursor gas and then a diamond-like carbon coat is applied using C₂H₂ precursor gas.

At the beginning of the deposition process, the pressure in the chamber may be drawn down to a pressure below atmospheric pressure, less than 760 Torr, and preferably in the range of 1×10⁻⁶ torr to 20×10⁻⁶ torr, including all values and ranges therein. During ion cleaning, the pressure in the process chamber is preferably maintained in the range of 1 to 100 millitorr, including all values and ranges therein, and the inert gas is preferably supplied at a flow rate in the range of 1 sccm to 200 sccm (standard cubic centimeters per minute), including all values and ranges therein and preferably 10 sccm to 30 sccm. A pulsed voltage is applied to the mesh cage with the first power supply to generate plasma from the inert gas. The pulsed voltage is preferably in the range of 1 kV to 5 kV, including all values and ranges therein and preferably 1 kV to 3 kV, at a frequency in the range of 0.5 kHz to 6 kHz, including all values and ranges therein and preferably 1 kHz to 4 kHz, and a pulse width in the range of 10 μs to 30 μs, including all values and ranges therein.

A voltage, and preferably a pulsed DC voltage, is applied to the component with the second power supply to draw plasma ions to the component and is set in the range of 50 V to 1,000 V. In the case of a pulsed DC voltage, the peak voltage is preferably set in the range of 50 V to 1000 V, including all values and ranges therein, and at a frequency in the range of 1 kHz to 200 kHz, including all values and ranges therein, and pulse width in the range of 0.5 μs to 5 μs, including all values and ranges, therein is preferably applied to the component to draw plasma ions to the component. Alternatively, a DC voltage in the range of 100 V to 1000 V including all values and ranges therein. Alternatively, an RF voltage may be applied to the components to draw the plasma ions to the components. The RF voltage is preferably in the range of 100 V to 1000 V, including all values and ranges therein, and at a frequency in the range of 100 kHz to 13.56 MHz, including all values and ranges therein, therein is preferably applied to the component to draw plasma ions to the component. Ion cleaning may proceed for a period of time in the range of 10 minutes to 120 minutes including all values and ranges therein.

In depositing the bond layer, the duration of deposition is preferably in the range of 10 minutes to 60 minutes, including all values and ranges therein. During bond layer deposition, the pressure in the process chamber is preferably maintained in the range of 10 mTorr to 100 mTorr, including all values and ranges therein and preferably 20 mTorr. The bond layer gas precursor is preferably supplied at a flow rate in the range of 10 sccm to 30 sccm, including all values and ranges therein, and more preferably 20 sccm. In addition, an inert gas, such as argon or helium, may optionally be supplied with the bond layer precursor gas at a flow rate in the range of 50 sccm, including all values and ranges therein. The pulsed voltage applied to the mesh cage with the first power supply to generate plasma from the precursor gas and inert gas, if present, is preferably set in the range of 1 kV to 3 kV, including all values and ranges therein and more preferably 2 kV, at a frequency in the range of 1 kHz to 4 kHz, including all values and ranges therein and more preferably 2 kHz, and a pulse width in the range of 10 μs to 30 μs, including all values and ranges therein and more preferably 20 μs.

The voltage, preferably a pulsed DC voltage, applied to the component with the second power supply to draw plasma ions to the component is preferably set in the range of 100 V to 800 V. In the case of a pulsed DC voltage, the pulsed DC peak voltage is preferably in the range of 400 to 800 V, including all values and ranges therein and more preferably 600 V, at a frequency of 100 to 300 kHz, including all values and ranges therein and more preferably 200 kHz, and at a current in the range of 0.1 to 1 A, including all values and ranges therein and more preferably from 0.58 to 0.6 A. Alternatively, a DC voltage in the range of 100 V to 800 V including all values and ranges therein is applied to the component.

In depositing the coating, such as a diamond like carbon coating or transition metal containing coating, the duration of deposition is preferably in the range of 1 hour to 20 hours, including all values and ranges therein, and preferably from 12 to 15 hours to obtain a thick DLC coating. During coating deposition, the pressure in the process chamber is preferably maintained in the range of 10 mTorr to 100 mTorr, including all values and ranges therein and more preferably 20 mTorr. The coating gas precursor is preferably supplied at a flow rate in the range of 50 sccm to 200 sccm, including all values and ranges therein, and more preferably 110 sccm. In addition, an inert gas, such as argon or helium, may optionally be supplied with the coating precursor gas at a flow rate in the range of 20 sccm to 200 sccm, including all values and ranges therein.

The pulsed voltage applied to the mesh cage with the first power supply to generate plasma from the precursor gas and the inert gas, if present, is preferably in the range of 1 kV to 3 kV, including all values and ranges therein and more preferably 2 kV, at a frequency in the range of 1 kHz to 4 kHz, including all values and ranges therein, and preferably 3 kHz, and a pulse width in the range of 10 to 30 μs, including all values and ranges therein and more preferably 20 μs. The voltage, preferably a pulsed DC voltage, applied to the component with the second power supply to draw plasma ions to the component is set in the range of 100 V to 800 V. In the case of a pulsed DC peak voltage, the voltage is preferably in the range of 400 V to 800 V, including all values and ranges therein and more preferably 600 V, and at a frequency in the range of 100 kHz to 300 kHz, including all values and ranges therein and more preferably 200 kHz, and current in the range of 0.1 A to 1.0 A, including all values and ranges and more preferably from 0.5 A to 0.7 A. Alternatively, a DC voltage in the range of 100 V to 800V including all values and ranges therein is applied to the component. It may be appreciated that if the bias voltage applied to the component is too high, a high internal stress generates in the film, thereby causing spallation of the film.

During coating the coating layer the average ion energy to the first order can be considered as the peak voltage applied on the parts with respect to ground times the single charge of the ionized gas species, and it is preferably in the range of 100 eV to 800 eV including all values and ranges therein. Excessive ion energy also may result in no net film deposition.

The bond layer, if present, preferably exhibits a thickness in the range of 0.1 μm to 5 μm, including all values and ranges therein. The coating preferably exhibits a thickness in the range of 1 μm to 40 μm, including all values and ranges therein. Where both the bond layer and the coating are present, the resulting coating may exhibit a total thickness in the range of 1 μm to 40 μm, including all values and ranges therein, and preferably in the range of 10 μm to 35 μm. In addition, the deposition rate for both the bond layer and coating is preferably in the range of 1.0 μm per hour to 3.0 μm per hour, including all values and ranges therein and preferably in the range of 1.0 microns per hour to 2.5 microns per hour. The hardness of the coating, as determined by nanoindentation under a 3 mN load using Hysitron Nanoindentor with Hysitron Triboscope, is preferably in the range of 10 GPa to 25 GPa, including all values and ranges therein. Hardness is specifically determined by generating a force (uN) and displacement (nm) plot where the force applied was in the range of 0-3 mN and displacement is in the range of 0-125 nm. The indenter was a Berkovich tip. Indentation curves are then generated and the hardness was calculated using Hysitron Triboscan TS/TI Platform V9.3.13.0 software which identifies a Martens hardness (HM) according to the express HM=Pmax/As where Pmax is the maximum load and As is the contact surface area, where As=24.5h²ₘₐₓ, where hₘₐₓ is the maximum displacement.

### Example

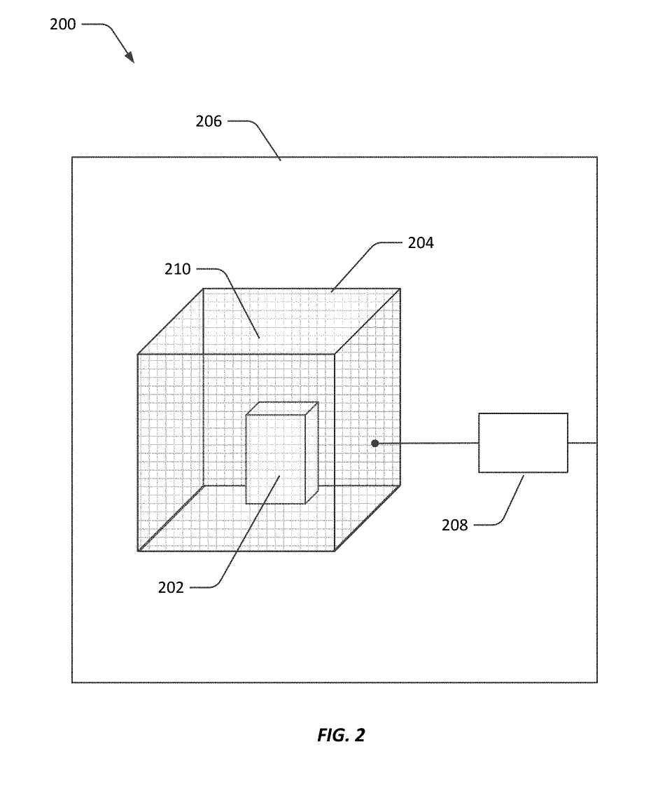

Four samples of diamond-like carbon coatings deposited on steel substrates were created using the process parameters described in Tables 1, 2 and 3 below. The first sample was formed using the system of FIG. 2 with a single power supply connected to the mesh cage. In addition, the component was electrically connected to the cage. The second through fourth samples were formed using the system described herein including a power supply connected to the mesh cage and a second power supply connected to the component. Prior to applying the coatings, the samples were cleaned for 90 minutes using argon plasma with the processing parameters shown in Table 1. After cleaning, a bond layer is deposited using the parameters shown in Table 2. Finally, a diamond-like carbon layer is deposited on top using the parameters shown in Table 3.

TABLE 1
Ion Cleaning Parameters

| | Ion Sputter Cleaning | | | | | | | | |
|---|---|---|---|---|---|---|---|---|---|
| | | | | Mesh Biasing | | | | | |
| | | | | Freq | VB | Ib | Part Biasing | | |
| | Time | Ar Flowrate | Press | (Hz)/PW | pk | pk | Freq | Vb | Ib |
| Sample | (min) | (sccm) | (mtorr) | (μs) | (kv) | (A) | (kHz) | (V) | (A) |

One Power Supply

| | | | | | | |
|---|---|---|---|---|---|---|
| 1 | 90 | 80 | 20 | 1k/20 | 5 | 90 |

Two Power Supplies

| | | | | | | | | | |
|---|---|---|---|---|---|---|---|---|---|
| 3 | 120 | 40 | 10 | 2k/20 | 2 | 2 | 200 | 600 | 0.64 |
| 4 | 90 | 40 | 10 | 2k/20 | 2 | 1.8 | 200 | 600 | 0.62 |
| 5 | 90 | 40 | 10 | 2k/20 | 2 | 2 | 200 | 600 | 0.64 |

TABLE 2
Bond Layer Deposition Parameters

| | | TMS | | Mesh Biasing | | | | |
|---|---|---|---|---|---|---|---|---|
| | | Flow- | | Freq | | Part Biasing | | |
| Sam- | Time | rate | Pressure | (Hz)/PW | Vb | Freq | Vb | Ib |
| ple | (min) | (sccm) | (mtorr) | (μs) | (kV) | (kHz) | (V) | (A) |

One Power Supply

| | | | | | |
|---|---|---|---|---|---|
| 1 | 30 | 20 | 10 | 500/20 | 8 |

Two Power Supplies

| | | | | | | | | |
|---|---|---|---|---|---|---|---|---|
| 2 | 30 | 20 | 10 | 2000/20 | 2 | 200 | 600 | 0.6 |
| 3 | 30 | 20 | 10 | 2000/20 | 2 | 200 | 600 | 0.58 |
| 4 | 30 | 20 | 10 | 2000/20 | 2 | 200 | 600 | 0.6 |

TABLE 3
Coating Deposition Parameters

| | | C₂H₂ | | Mesh Biasing | | | | |
|---|---|---|---|---|---|---|---|---|
| | | Flow- | | Freq | | Part Biasing | | |
| Sam- | Time | rates | Pressure | (Hz)/PW | Vb | Freq | Vb | Ib |
| ple | (Hours) | (sccm) | (mtorr) | (μs) | (kV) | (kHz) | (V) | (A) |

One Power Supply

| | | | | | |
|---|---|---|---|---|---|
| 1 | 7 | 100 | 10 | 500/20 | 8 |

Two Power Supplies

| | | | | | | | | |
|---|---|---|---|---|---|---|---|---|
| 2 | 15 | 110 | 20 | 3000/20 | 2 | 200 | 600 | 0.7 |
| 3 | 12.5 | 110 | 20 | 3000/20 | 2 | 200 | 600 | 0.5 |
| 4 | 14 | 110 | 20 | 3000/20 | 2 | 200 | 600 | 0.6 |

The resultant samples were then analyzed for total thickness and hardness. Coating thickness was obtained from scanning electron microscope images taken of cross-sections of the coatings on the samples. The deposition rate was determined based on deposition time and the measured thickness. The nanohardness was measured under a 3 mN load using Hysitron Nanoindentor with Hysitron Triboscope. The results are shown in Table 4.

TABLE 4
Results

| | | | |
|---|---|---|---|
| Sample | Total Thickness (μm) | Deposit Rate (μm/h) | H nano (GPa) |

One Power Supply

| | | | |
|---|---|---|---|
| 1 | 25 | 3.5 | 8.2 |

Two Power Supplies

| | | | |
|---|---|---|---|
| 2 | 31.2 | 2.1 | 15.82 |
| 3 | 17.8 | 1.4 | 21.59 |
| 4 | 32.1 | 2.3 | 13.87 |

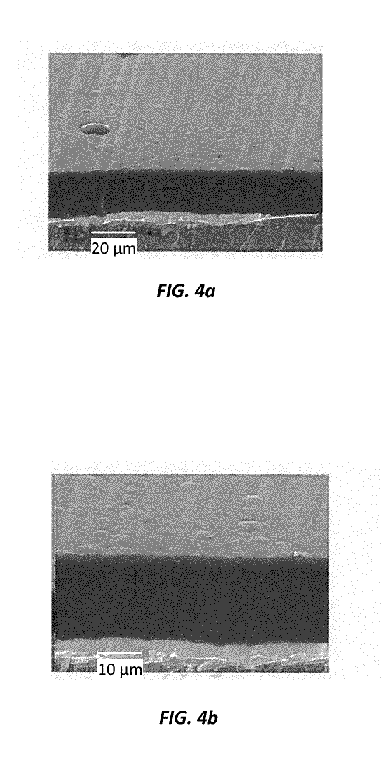

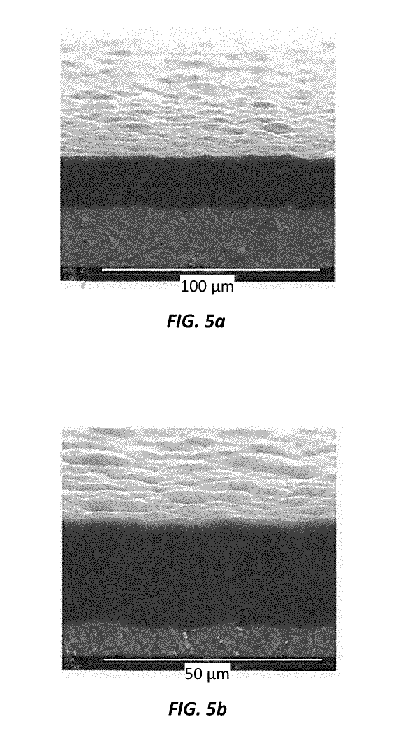

FIGS. 4a and 4b are the SEM images taken of the cross-section of the first sample and FIGS. 5a and 5b are the SEM images taken of the cross-section of the fourth sample. The images illustrate that the presently described process provides a coating that exhibits less, or eliminates, the ridges and droplets seen in FIGS. 4a and 4b created by the single power source process. This may be due to the relatively high ion energy bombardment of the process described herein.

The data indicates a 17.8 to 32.1 μm total coating thickness was achieved at a deposition rate in the range of 1.4 to 2.1 μm per hour in samples 2 through 4 (produced by the process and methods described herein). The total coating thickness of sample 1, produced using the system of FIG. 2, was 25 μm deposited at a rate of 3.5 μm/hour. The hardness of sample 1 was 8.2 GPa and increased to values in the range of 14 to 22 GPa for the second through fourth samples. Accordingly, even though samples 2 through 4 exhibited a relatively lower deposition rate, these samples exhibited greater hardness, which may be attributed to relatively higher ion energy than that produced by the process of sample 1.

It is also noted that the average ion energy for the process of FIG. 2 is estimated to be less than a few tens of eV's, whereas the ion energy of the presently described process is estimated to be a few 100 eV's. This relatively higher energy bombardment during film growth is understood to increase film density and hardness.

The systems and processes herein may be utilized to form coatings on a variety of components. The components may include those components having through holes or blind holes, such a firearm components, syringes, tubes, pipes, valves, etc.; including, components exhibiting relatively complex geometries, such as trigger assemblies. Firearms may be understood as an apparatus that launches one or more projectiles by pressurization due to combustion or a propellent. The disclosed method can be applied to coat piston rings where a thick, hard and wear resistant coating with low friction is needed. On the other hand, for other automotive components such as the camshaft, crankshaft, tappets, gears and etc., a thin coating may be obtained by a short deposition duration.

The foregoing description of several methods and embodiments has been presented for purposes of illustration. It is not intended to be exhaustive or to limit the claims to the precise steps and/or forms disclosed, and obviously many modifications and variations are possible in light of the above teaching. It is intended that the scope of the invention be defined by the claims appended hereto.

1. A method of forming a coating, comprising:
providing a component within a mesh cage in a chamber, wherein said mesh cage is coupled to a first power supply;
coupling said component to a second power supply;
reducing the pressure within said chamber to a pressure less than atmospheric pressure;
depositing a coating on said component, wherein depositing said coating includes:
supplying a coating precursor gas to said chamber at a rate in the range of 50 sccm to 200 sccm;
applying a pulsed voltage to said mesh cage with said first power supply generating a plasma, wherein said pulsed voltage is set in the range of 1 kV to 3 kV, a frequency in the range of 1 kHz to 4 kHz, and a pulsed width in the range of 10 μs to 30 μs;
applying a voltage to said component with said second power supply, wherein said voltage is set in the range of 100 V to 800 V; and
wherein said pulsed voltage and said voltage are applied for a period of time in the range of 1 hour to 20 hours.

2. The method of claim 1, wherein said voltage applied to said component is a DC voltage set in the range of 100 V to 800 V.

3. The method of claim 1, wherein said voltage applied to said component is a pulsed DC voltage set in the range of 400 V to 800 V exhibiting a frequency in the range of 100 kHz to 300 kHz and a current of 0.1 A to 1 A.

4. The method of claim 1, wherein said precursor gas is a diamond-like coating precursor or a transition metal containing precursor.

5. The method of claim 1, wherein said precursor gas is acetylene.

6. The method of claim 1, further comprising depositing a bond layer on said component prior to depositing said coating, wherein depositing said bond layer includes:
supplying a bond layer precursor gas to said chamber at a rate in the range of 10 sccm to 30 sccm;
applying said pulsed voltage to said mesh cage with said first power supply generating a plasma, wherein said pulsed voltage is set in the range of 1 kV to 3 kV, at a frequency in the range of 1 kHz to 4 kHz, and a pulsed width in the range of 10 μs to 30 μs;
applying said voltage to said component, wherein said voltage is set in the range of 100 V to 800 V; and
forming a bond layer on said component, wherein said second pulsed voltage and said second voltage is applied for a period of time in the range of 10 minutes to 60 minutes and said coating is then formed on said bond layer.

7. The method of claim 6, wherein said bond layer precursor gas includes silicon.

8. The method of claim 1, further comprising cleaning said component prior to depositing said coating, wherein cleaning said component comprises:
supplying an inert gas to said chamber at a rate in the range of 1 sccm to 200 sccm;
applying said pulsed voltage to said mesh cage with said first power supply generating a plasma, wherein said pulsed voltage is set in the range of 1 kV to 5 kV, at a frequency in the range of 0.5 kHz to 6 kHz, and a pulsed width in the range of 10 μs to 30 μs; and
applying said voltage to said component, wherein said voltage is set in the range of 50 V to 1,000 V.

9. The method of claim 1, wherein said coating is deposited at a rate of 1.0 to 3.0 μm per hour.

10. The method of claim 1, wherein said coating is deposited to a total thickness in the range of 1 μm to 40 μm.

11. The method of claim 1, wherein said coating exhibits a hardness, as determined by nanoindentation, in the range of 10 GPa to 25 GPa.

12. The method of claim 1, wherein said component is a firearm component.

13. A diamond-like coated component, comprising:
a component having a surface; and
a diamond-like coating deposited on said surface, wherein said diamond-like coating exhibits a thickness in the range of 1 μm to 40 μm and a hardness, as determined by nanoindentation, in the range of 10 GPa to 25 GPa.
